(19) United States
(12) Patent Application Publication
(10) Pub. No.: US 2025/0291391 A1
(43) Pub. Date: Sep. 18, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: HIROTSUGU KISHIMOTO, Yongin-si (KR); Jongbin Park, Yongin-si (KR); MINSOK JANG, Yongin-si (KR); Junhun Cha, Yongin-si (KR); SUNGGUK AN, Yongin-si (KR); CHUL HO JEONG, Yongin-si (KR)

(21) Appl. No.: 19/011,297

(22) Filed: Jan. 6, 2025

(30) Foreign Application Priority Data
Mar. 12, 2024 (KR) 10-2024-0034286

(51) Int. Cl. G06F 1/16

(52) U.S. Cl. CPC G06F 1/1656; G06F 1/1616

(57) ABSTRACT

A display device and a method of manufacturing a display device are disclosed. A display device includes a display panel including a folding area and a plate located below the display panel, and defining a plurality of openings extending continuously in a first direction and spaced apart from each other in a second direction intersecting the first direction, and a value obtained by dividing a width of each of the openings in the second direction by a separation distance of adjacent openings among the openings in the second direction is 0.05 to 0.5.

### CROSS-REFERENCE TO RELATED APPLICATION

The present application claims priority to and the benefit of Korean Patent Application No. 10-2024-0034286, filed on Mar. 12, 2024 in the Korean Intellectual Property Office, the entire disclosure of which is incorporated herein by reference.

### BACKGROUND

### 1. Field

Aspects of embodiments of the present disclosure relate to a display device, a method of manufacturing the display device, and an electronic device including the display device.

### 2. Discussion of the Related Art

Recently, a display field that processes and displays information has developed rapidly, and, accordingly, many technologies for large-area foldable mobile displays are being developed. Since these flexible display devices generally must be capable of folding and unfolding, a display panel has a structure in which display elements are formed on a very thin polymer substrate, which has a problem of low impact resistance. Therefore, a back plate is applied to protect the display panel. As part of these display devices, foldable type electronic devices are continuously being released, and an improved support structure for a foldable display may be desired.

### SUMMARY

According to an aspect of embodiments of the present disclosure, a display device that provides visual information a method of manufacturing the display device, and an electronic device including the display device are provided. According to another aspect of embodiments of the present disclosure, a display device with improved stability and reliability, a method of manufacturing the display device, and an electronic device including the display device are provided.

According to an aspect of embodiments of the present disclosure, a method of manufacturing the display device is provided.

According to one or more embodiments of the present disclosure, a display device includes a display panel including a folding area and a plate located below the display panel, and defining a plurality of openings extending continuously in a first direction and spaced apart from each other in a second direction intersecting the first direction, and a value obtained by dividing a width of each of the openings in the second direction by a separation distance of adjacent openings among the openings in the second direction is 0.05 to 0.5.

In one or more embodiments, each of the openings may entirely penetrate the plate in the first direction.

In one or more embodiments, a value obtained by dividing the separation distance by a length of the plate in the first direction may be 0.003 to 0.04.

In one or more embodiments, a length of each of the openings in the first direction may be equal to a length of the plate in the first direction.

In one or more embodiments, the openings may be defined in the folding area below the display panel.

In one or more embodiments, the display device may further include an adhesive film between the display panel and the plate, and a cover film below the plate.

In one or more embodiments, the adhesive film and the openings may overlap in the folding area in a plan view.

In one or more embodiments, a planar area of the plate may be equal to at least one of a planar area of the adhesive film or the cover film.

In one or more embodiments, the width of each of the openings may be 20 μm to 1000 μm, and the separation distance may be 200 μm to 5000 μm.

In one or more embodiments, the plate may include at least one of a plastic, a metal, or glass.

In one or more embodiments, the plastic may include at least one of carbon fiber reinforced plastic (CFRP) or glass fiber reinforced plastic (GFRP).

In one or more embodiments, the metal may include at least one of stainless steel, aluminum, magnesium, or copper.

According to one or more embodiments of the present disclosure, a method of manufacturing a display device includes forming a plurality of openings in a preliminary plate using a laser, the openings continuously extending in a first direction and spaced apart from each other in a second direction intersecting the first direction, attaching a preliminary film to a surface of the preliminary plate and forming a plate to which a film is attached by cutting the preliminary plate and the preliminary film concurrently along a closed loop-shaped cutting line.

In one or more embodiments, the openings may be formed such that a width of each of the openings in the second direction divided by a separation distance of adjacent openings among the openings in the second direction is 0.05 to 0.5

In one or more embodiments, the width of each of the openings may be 20 μm to 1000 μm, and the separation distance between the adjacent openings in the second direction may be 200 μm to 5000 μm.

In one or more embodiments, the preliminary plate and the preliminary film may be cut such that a value obtained by dividing the separation distance between the adjacent openings by a length of the plate in the first direction may be 0.003 to 0.04.

In one or more embodiments, a cutting area defined by the cutting line may overlap the openings in a plan view.

In one or more embodiments, after forming the plate to which the film is attached, a length of each of the openings in the first direction may be equal to a length of the plate in the first direction.

In one or more embodiments, a planar area of the plate and a planar area of the film may be the same.

In one or more embodiments, the preliminary plate and the preliminary film may be cut using a laser.

According to one or more embodiments of the present disclosure, an electronic device includes a display device and a processor configured to drive the display device, and wherein the display device includes a display panel comprising a folding area and a plate located below the display panel, and defining a plurality of openings extending continuously in a first direction and spaced apart from each other in a second direction intersecting the first direction, and a value obtained by dividing a width of each of the openings in the second direction by a separation distance of adjacent openings among the openings in the second direction is 0.05 to 0.5. A display device according to one or more embodiments of the present disclosure may include a display panel including a folding area and a plate located below the display panel, and defining a plurality of openings extending continuously in a first direction and spaced apart from each other in a second direction intersecting the first direction, and a value obtained by dividing a width of each of the openings in the second direction by a separation distance of adjacent openings among the openings in the second direction is 0.05 to 0.5.

Accordingly, as a width and a separation distance of each of the openings have the above ratio, an impact resistance of the display device including the plate may be improved, folding reliability may be improved, and wrinkles may be prevented or substantially prevented. In addition, because the openings are continuously extended, product productivity may be improved and costs may be reduced. In addition, the width of the openings is reduced such that patterns caused by the openings are not visible from the outside, thereby providing users with a display device with improved stability and reliability.

### BRIEF DESCRIPTION OF THE DRAWINGS

The accompanying drawings, which are included to provide a further understanding of the inventive concept and are incorporated in and constitute a part of this specification, illustrate some embodiments of the inventive concept together with the description.

FIG. 1 is a plan view of a display device according to an embodiment of the present disclosure.

FIG. 2 is a cross-sectional view showing a folding state of the display device of FIG. 1.

FIG. 3 is a cross-sectional view of the display device of FIG. 1, taken along the line I-I′.

FIG. 4 is a cross-sectional view showing a display panel of FIG. 3, according to an embodiment.

FIG. 5 is a cross-sectional view showing a plate of FIG. 3, according to an embodiment.

FIGS. 6 to 11 are views showing a method of manufacturing a display device according to an embodiment of the present disclosure.

FIG. 12 is schematic view showing a laser cutter used in FIG. 6 and FIG. 8, according to an embodiment.

FIG. 13 is block-diagram for showing an electronic device according to an embodiment of the disclosure.

FIG. 14 is schematic views for showing the electronic device according to various embodiments of FIG. 13.

### DETAILED DESCRIPTION

Some illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

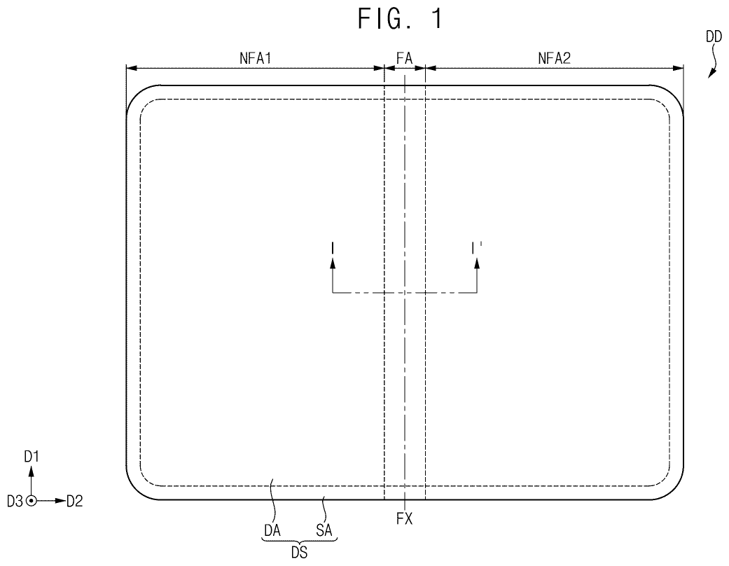

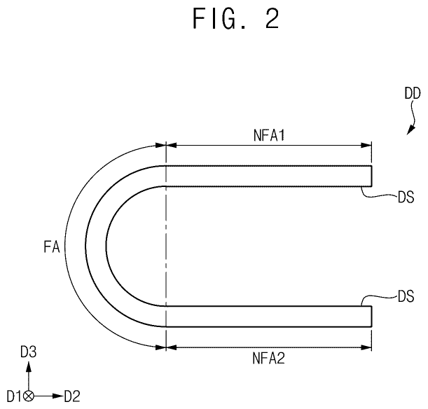

FIG. 1 is a plan view of a display device according to an embodiment of the present disclosure. FIG. 2 is a cross-sectional view showing a folding state of the display device of FIG. 1.

Referring to FIGS. 1 and 2, a top surface of the display device DD may be defined as a display surface DS. The display surface DS may have a plane defined by the first direction D1 and the second direction D2. An image generated by the display device DD may be provided to a user through the display surface DS.

The display surface DS may include a display area DA and a peripheral area SA. The display area DA may display an image, and the peripheral area SA may not display an image. The peripheral area SA may be disposed around the display area DA. For example, the peripheral area SA may surround the display area DA in a plan view.

The display device DD may be a flexible display device. The display device DD may be a foldable display device that may be folded or unfolded. The display device DD may include a first area NFA1, a second area NFA2, and a third area FA. The second area NFA2 may be spaced apart from the first area NFA1 in the second direction D2. The third area FA may be disposed between the first area NFA1 and the second area NFA2.

The third area FA may be bent relative to a folding axis FX parallel to the first direction D1, such that the display device DD may be folded. In an embodiment, as shown in FIG. 2, the display device DD may be in-folded such that the display surface DS is not exposed to an outside. That is, when the display device DD is folded, the first area NFA1 and the second area NFA2 of the display surface DS may face each other. In another embodiment, the display device DD may be out-folded such that the display surface DS is exposed to an outside.

The first area NFA1, the second area NFA2, and the third area FA may be referred to as a first non-folding area, a second non-folding area, and a folding area, respectively. In an embodiment, as shown in FIG. 1, the display device DD may include two non-folding areas (the first area NFA1 and the second area NFA2) and one folding area (the third area FA). Although shown, this is an example and the present disclosure is not limited thereto. For example, the display device DD may include three or more non-folding areas and two or more folding areas disposed between the non-folding areas.

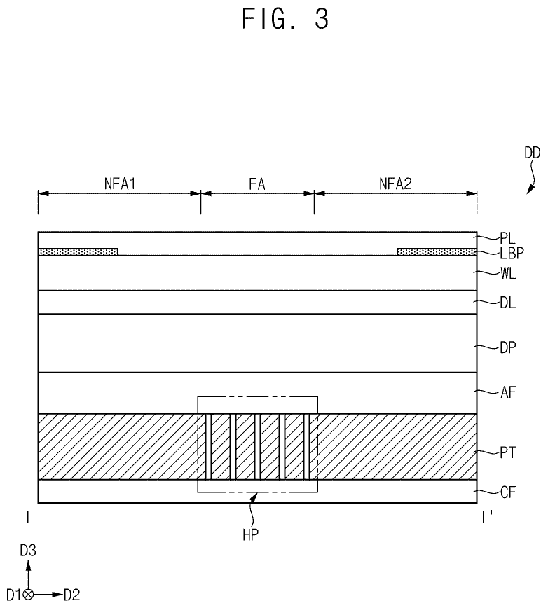

FIG. 3 is a cross-sectional view of the display device of FIG. 1, taken along the line I-I′.

In an embodiment, the display device DD may include a cover film CF, a plate PT, an adhesive film AF, a display panel DP, a damping layer DL, a window layer WL, a light blocking pattern LBP, and a protective film PL.

The cover film CF may be disposed on a back of the display device DD to protect the display device DD from external impacts. For example, the cover film CF may include at least one of polyurethane (PU), thermoplastic polyurethane (TPU), silicone, and polydimethylacrylamide (PDMA). These may be used alone or in combination with each other. However, embodiments of the present disclosure are not limited thereto.

The plate PT may be disposed on the cover film CF. The plate PT may support the display panel DP and protect the display device DD from external impacts. Openings HP may be defined in a portion of the plate PT. For example, the openings HP may overlap the folding area FA in a plan view.

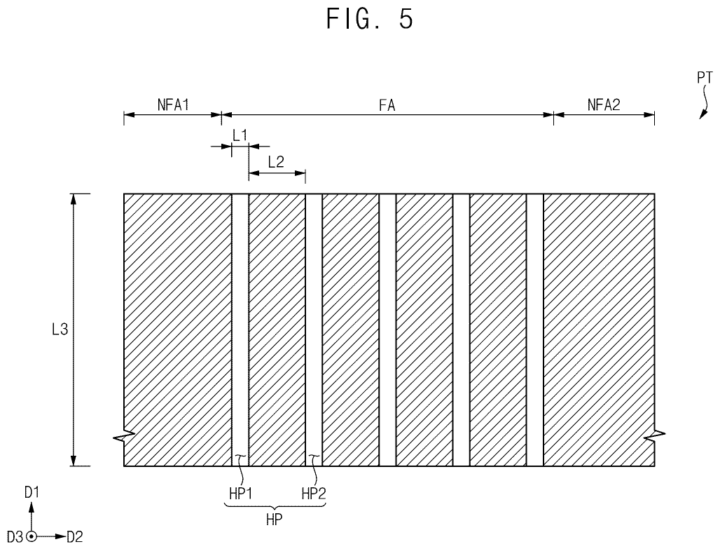

In an embodiment, the plate PT may have a same (same or substantially same) planar area as at least one of the cover film CF and the adhesive film AF. For example, as shown in FIG. 5, the plate PT may have a difference of about 10 μm or less from the cover film CF and/or the adhesive film AF in the first direction D1 and/or the second direction D2. However, embodiments of the present disclosure is not limited thereto. The plate PT will be described below in further detail with reference to FIG. 5.

The adhesive film AF may be disposed on the plate PT. The adhesive film AF may adhere the plate PT and components disposed thereon. For example, the adhesive film AF may adhere the plate PT and the display panel DP. The adhesive film AF may include a pressure sensitive adhesive (PSA), an optical clear adhesive (OCA), or an optical clear resin (OCR). However, embodiments of the present disclosure are not limited thereto.

In an embodiment, the adhesive film AF may overlap the openings HP of the plate PT in a plan view. That is, the adhesive film AF may cover an upper surface of the plate PT without being open at a location where it overlaps the openings HP of the plate PT. Accordingly, the adhesive film AF may block, minimize, or reduce light coming from a back of the openings HP.

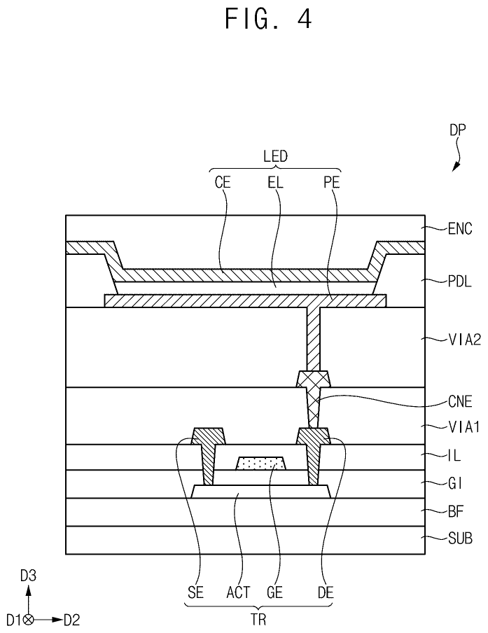

The display panel DP may be disposed on the adhesive film AF. The display panel DP may receive electrical signals and emit light such that the display device DD may provide visual information to users. For example, the display panel DP may be either organic light emitting or inorganic light emitting. However, embodiments of the present disclosure are not limited thereto. The display panel DP will be described in further detail later with reference to FIG. 4.

The damping layer DL may be disposed on the display panel DP. The damping layer DL may include a multi-layer structure or a single-layer structure. The damping layer DL may protect the display panel DP from external shock. For example, the damping layer DL may be made of any of polyimide, polycarbonate, polyamide, triacetylcellulose, polymethylmethacrylate, and polyethylene terephthalate. These may be used alone or in combination with each other. However, embodiments of the present disclosure are not limited thereto. In an embodiment, the damping layer DL may be omitted.

The window layer WL may be disposed on the damping layer DL. The window layer WL may include a substantially transparent material. For example, the window layer WL may be glass or plastic. However, embodiments of the present disclosure are not limited thereto.

A light blocking pattern LBP may be disposed on the window layer WL. The light blocking pattern LBP may be disposed in the peripheral area (e.g., peripheral area SA in FIG. 1). The light blocking pattern LBP may block light coming from the display device DD in the third direction D3. In an embodiment, the light blocking pattern LBP may include black dye. For example, the light blocking pattern LBP may include at least one of carbon black (CB) and titanium black (TiBK). These may be used alone or in combination with each other. However, embodiments of the present disclosure are not limited thereto.

The protective film PL may be disposed on the window layer WL. The protective film PL may be disposed on the window layer WL and cover the light blocking pattern LBP. The protective film PL may protect the window layer WL from front impacts, scratches, etc. For example, the protective film PL may include at least one of a base layer, a hard coating layer, a low refractive index layer, and an anti-fingerprint layer. However, embodiments of the present disclosure are not limited thereto.

FIG. 4 is a cross-sectional view showing a display panel of FIG. 3, according to an embodiment.

In an embodiment, referring to FIGS. 3 and 4, the display panel DP may include a substrate SUB, a buffer layer BF, a gate insulating layer GI, a transistor TR, an interlayer insulating layer IL, a connecting electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not limited thereto, and the substrate SUB may be an inorganic layer, an organic layer, or a composite material layer.

The buffer layer BF may be disposed on the substrate SUB. The buffer layer BF may be disposed on the substrate SUB. The buffer layer BF may prevent or substantially prevent impurities, such as oxygen and moisture, from penetrating into an upper part of the substrate SUB. In an embodiment, the buffer layer BF may include an inorganic insulating material.

The active layer ACT may be disposed on the buffer layer BF. The active layer ACT may include an oxide semiconductor, a silicon semiconductor, an organic semiconductor, etc. For example, the oxide semiconductor may include at least one oxide from indium (In), gallium (Ga), tin (Sn), zirconium (Zr), vanadium (V), hafnium (Hf), cadmium (Cd), germanium (GE), chromium (Cr), titanium (Ti), and zinc (Zn). The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BF. The gate insulating layer GI may cover the active layer ACT on the buffer layer BF. In an embodiment, the gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material, such as a metal, an alloy, conductive metal nitride, conductive metal oxide, or transparent conductive material. Examples of the conductive material that may be used in the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. In an embodiment, the gate electrode GE may have a single-layer structure or a multi-layer structure including a plurality of conductive layers.

The interlayer insulating layer IL may be disposed on the gate electrode GE. The interlayer insulating layer IL may be disposed on the gate insulating layer GI and cover the gate electrode GE on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. The first via layer VIA1 may be disposed on the interlayer insulating layer IL and cover the source electrode SE and the drain electrode DE on the interlayer insulating layer IL. In an embodiment, the first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include a metal, an alloy, metal nitride, conductive metal oxide, transparent conductive material, etc. These may be used alone or in combination with each other. However, embodiments of the present disclosure are not limited thereto.

The second via layer VIA2 may be disposed on the connection electrode CNE. The second via layer VIA2 may be disposed on the first via layer VIA1 and cover the connection electrode CNE. In an embodiment, the second via layer VIA2 may include a same or substantially a same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. The light emitting layer EL may be disposed within an opening defined by the pixel defining layer PDL. That is, the light emitting layer EL may be surrounded by the pixel defining layer PDL. The light emitting layer EL may include at least one of an organic light emitting material and/or quantum dots. However, embodiments of the present disclosure are not limited thereto.

The common electrode CE may be disposed on the light emitting layer EL. The common electrode CE may also be disposed on the pixel defining layer PDL. That is, the common electrode CE may be continuously disposed on the light emitting layer EL and the pixel defining layer PDL. The common electrode CE may include a conductive material. The light emitting layer EL may emit light based on a voltage difference between the pixel electrode PE and the common electrode CE.

The encapsulation layer ENC may be disposed on the common electrode CE. In an embodiment, the encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a cured polymer, such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, titanium oxide, etc.

FIG. 5 is a cross-sectional view showing a plate of FIG. 3, according to an embodiment.

Referring to FIGS. 3 and 5, the plate PT may include the openings HP defined to continuously extend in the first direction D1. For example, each of the openings HP may be a line that is continuously cut without a break in the plate PT in the first direction D1. That is, in an embodiment, the openings HP may entirely penetrate the plate PT in the first direction D1. Each of the openings HP may be spaced apart from each other in the second direction D2.

In an embodiment, each of the openings HP of the plate PT may have a width of a first length L1 in the second direction D2. In an embodiment, the first length L1 may be 20 μm (20 μm or about 20 μm) or more and 1000 μm (1000 μm or about 1000 μm) or less. In an embodiment, the first length L1 may be 20 μm (20 μm or about 20 μm) or more and 40 μm (40 μm or about 40 μm) or less.

The adjacent openings HP among the openings HP of the plate PT may be spaced apart by a distance having a second length L2 in the second direction D2. In an embodiment, the second length L2 may be 200 μm (200 μm or about 200 μm) or more and 5000 μm (5000 μm or about 5000 μm) or less. In an embodiment, the second length L2 may be 200 μm (200 μm or about 200 μm) or more and 1000 μm (1000 μm or about 1000 μm) or less.

In an embodiment, a length ratio (L1/L2) of the first length L1 and the second length L2 of the plate PT may be 0.05 (0.05 or about 0.05) or more and 0.5 (0.5 or about 0.5) or less. In an embodiment, a length ratio of the first length L1 and the second length L2 of the plate PT may be 0.05 (0.05 or about 0.05) or more and 0.2 (0.2 or about 0.2) or less. If a length ratio of the first length L1 and the second length L2 is outside the range described above, an impact resistance and folding reliability of the display device DD may be reduced.

In an embodiment, the plate PT may have a third length L3 in the first direction D1. In an embodiment, a length ratio (L2/L3) of the second length L2 and the third length L3 of the plate PT may be 0.003 (0.003 or about 0.003) or more and 0.04 (0.04 or about 0.04) or less. In an embodiment, a length ratio of the second length L2 and the third length L3 of the plate PT may be 0.003 (0.003 or about 0.003) or more and 0.02 (0.02 or about 0.02) or less. If a length ratio of the second length L2 and the third length L3 of the plate PT is less than 0.003, a strength of the plate PT may be weakened and an impact resistance of the display device DD may be weakened. If a length ratio of the second length L2 and the third length L3 of the plate PT is greater than 0.003, folding reliability of the display device DD may deteriorate.

As a result, as a width and a separation distance of each of the openings HP have the above ratio, an impact resistance of the display device DD including the plate PT may be improved, folding reliability may be improved, and wrinkles may be prevented or substantially prevented. In addition, because the openings HP are continuously extended, product productivity may be improved and costs may be reduced. In addition, as a width of the openings HP is reduced such that patterns caused by the openings HP may not be visible from the outside, users may be provided with a display device with improved stability and reliability.

In an embodiment, the third length L3 of the plate PT may be equal to a length of each of the openings HP in the first direction D1. For example, the plate PT may have a rectangular shape in a plan view. However, embodiments of the present disclosure are not limited thereto.

In an embodiment, the plate PT may include at least one of a plastic, a metal, and glass. For example, the plastic included in the plate PT may include at least one of carbon fiber reinforced plastic (CFRP) and glass fiber reinforced plastic (GFRP). The metal included in the plate PT may include at least one of stainless steel, aluminum, magnesium, and copper. These may be used alone or in combination with each other. However, embodiments of the present disclosure are not limited thereto.

Table 2 below shows results of evaluating an impact resistance and folding reliability of plates according to some Examples and Comparative Examples.

Impact resistance was evaluated through a ball-drop test. In the ball-drop test, a 5.6 g metal ball was dropped from a predetermined height onto a plate, and damage to the plate was observed with the naked eye. Table 2 lists a minimum height at which plate cracking occurs.

Folding reliability was evaluated through strain measurement experiments and wrinkle measurement experiments. In the deformation measurement experiment, a folding and unfolding of the plate was repeated multiple times to measure whether a shape was deformed. Table 2 lists a number of times folding and unfolding operations were repeated and whether a result was satisfactory. Specifically, folding and unfolding operations were repeated, and a good case was evaluated as “OK”, and a bad case was evaluated as “NG”.

In the wrinkle measurement experiment, the plate was fixed in a folded state for 2 hours at a temperature of 60 degrees Celsius, and a height of the wrinkles formed on the film attached to one side of the plate was measured.

Table 1 below shows materials of the plates, a width of the openings defined in the plates (e.g., the first length L1), and a separation distance between the openings (e.g., the second length L2), a value obtained by dividing a width by a separation distance according to the Examples and Comparative Examples in Table 2.

Referring to Table 1 below, Examples 1 to 12 are examples of plates according to some embodiments in which a value obtained dividing the first length L1 by the second length L2 satisfies 0.05 or more and 0.5 or less. Comparative Examples 1 to 4 are examples of plates in which a value obtained by dividing the first length L1 by the second length L2 does not satisfy 0.05 or more and 0.5 or less.

For example, in Example 1, the first length L1, which is a length of the width of each of the openings formed in the plate, is 40 μm, and the second length L2, which is a separation distance between adjacent openings among the openings, is 500 μm. That is, a value obtained by dividing the first length L1 of the plate by the second length L2 was 0.08. In Example 1, carbon fiber reinforced plastic (CFRP) was selected as the material for the plate PT. Likewise, in Examples 2 to Comparative Example 4, experiments were conducted by forming plates as shown in Table 1 below.

TABLE 1

| | | | separation | width/ |
|---|---|---|---|---|
| | | width | distance | separation |
| | material | (μm) | (μm) | distance |
| Example 1 | CFRP | 40 | 500 | 0.08 |
| Example 2 | CFRP | 25 | 500 | 0.05 |
| Example 3 | CFRP | 50 | 500 | 0.1 |
| Example 4 | CFRP | 40 | 200 | 0.2 |
| Example 5 | CFRP | 20 | 400 | 0.05 |
| Example 6 | CFRP | 40 | 800 | 0.05 |
| Example 7 | CFRP | 100 | 500 | 0.2 |
| Example 8 | CFRP | 100 | 200 | 0.5 |
| Example 9 | SUS | 40 | 500 | 0.08 |
| Example 10 | CFRP | 120 | 500 | 0.24 |
| Example 11 | CFRP | 100 | 1100 | 0.09 |
| Example 12 | CFRP | 50 | 180 | 0.28 |
| Comparative | SUS | 150 | 100 | 1.5 |
| Example 1 | | | | |
| Comparative | Al Alloy | 150 | 100 | 1.5 |
| Example 2 | | | | |
| Comparative | CFRP | 150 | 100 | 1.5 |
| Example 3 | | | | |
| Comparative | CFRP | 20 | 500 | 0.04 |
| Example 4 | | | | |

TABLE 2

| | minimum height | folding operation | | wrinkle height |
|---|---|---|---|---|
| | (cm) | times | | (μm) |
| Example 1 | 5 | 200,000 | (OK) | 60 |
| Example 2 | 5 | 100,000 | (OK) | 60 |
| Example 3 | 4 | 200,000 | (OK) | 60 |
| Example 4 | 4 | 200,000 | (OK) | 60 |
| Example 5 | 5 | 100,000 | (OK) | 60 |
| Example 6 | 5 | 100,000 | (OK) | 60 |
| Example 7 | 4 | 200,000 | (OK) | 60 |
| Example 8 | 4 | 200,000 | (OK) | 60 |
| Example 9 | 5 | 200,000 | (OK) | 60 |
| Example 10 | 3 | 100,000 | (OK) | 60 |
| Example 11 | 5 | 1000 | (NG) | 60 |
| Example 12 | 3 | 1000 | (NG) | 60 |
| Comparative | 3 | 200,000 | (OK) | 100 |
| Example 1 | | | | |
| Comparative | 3 | 200,000 | (OK) | 100 |
| Example 2 | | | | |
| Comparative | 1 | 200,000 | (OK) | 100 |
| Example 3 | | | | |
| Comparative | 5 | 1000 | (NG) | 60 |
| Example 4 | | | | |

Referring to Table 1 and Table 2, in Example 1, it can be seen that a minimum height at which the plate broke was 5 cm, a shape was not deformed even after folding and unfolding operations were repeated 200,000 times, and a wrinkle height was 60 μm.

In Example 2, it can be seen that a minimum height at which the plate breaks is 5 cm, a shape is not deformed even when the folding and unfolding operations are repeated 100,000 times, and a wrinkle height is 60 μm.

In Example 3, it can be seen that a minimum height at which the plate breaks is 4 cm, a shape is not deformed even when the folding and unfolding operations are repeated 200,000 times, and a wrinkle height is 60 μm.

In Example 4, it can be seen that a minimum height at which the plate breaks is 4 cm, a shape is not deformed even when the folding and unfolding operations are repeated 200,000 times, and a wrinkle height is 60 μm.

In Example 5, it can be seen that a minimum height at which the plate breaks is 5 cm, a shape is not deformed even when the folding and unfolding operations are repeated 100,000 times, and a wrinkle height is 60 μm.

In Example 6, it can be seen that a minimum height at which the plate breaks is 5 cm, a shape is not deformed even when the folding and unfolding operations are repeated 100,000 times, and a wrinkle height is 60 μm.

In Example 7, it can be seen that a minimum height at which the plate breaks is 4 cm, a shape is not deformed even when the folding and unfolding operations are repeated 200,000 times, and a wrinkle height is 60 μm.

In Example 8, it can be seen that a minimum height at which the plate breaks is 4 cm, a shape is not deformed even when the folding and unfolding operations are repeated 200,000 times, and a wrinkle height is 60 μm.

In Example 9, it can be seen that a minimum height at which the plate breaks is 5 cm, a shape is not deformed even when the folding and unfolding operations are repeated 200,000 times, and a wrinkle height is 60 μm.

In Example 10, it can be seen that a minimum height at which the plate breaks is 3 cm, a shape is not deformed even when the folding and unfolding operations are repeated 100,000 times, and a wrinkle height is 60 μm.

In Example 11, it can be seen that a minimum height at which the plate breaks is 5 cm, a shape is deformed when the folding and unfolding operations are repeated 1000 times, and a wrinkle height is 60 μm.

In Example 12, it can be seen that a minimum height at which the plate breaks is 3 cm, a shape is deformed even when the folding and unfolding operations are repeated 1000 times, and a wrinkle height is 60 μm.

In Comparative Example 1, it can be seen that a minimum height at which the plate breaks is 3 cm, a shape is not deformed even when the folding and unfolding operations are repeated 200,000 times, and a wrinkle height is 100 μm.

In Comparative Example 2, it can be seen that a minimum height at which the plate breaks is 3 cm, a shape is not deformed even when the folding and unfolding operations are repeated 200,000 times, and a wrinkle height is 100 μm.

In Comparative Example 3, it can be seen that a minimum height at which the plate breaks is 1 cm, a shape is not deformed even when the folding and unfolding operations are repeated 200,000 times, and a wrinkle height is 100 μm.

In Comparative Example 4, it can be seen that a minimum height at which the plate breaks is 5 cm, a shape is deformed even when the folding and unfolding operations are repeated 1000 times, and a wrinkle height is 60 μm.

As a result, it can be confirmed that in Examples 1 to 12 in which a value obtained by dividing the first length L1 by the second length L2 satisfies 0.05 or more and 0.5 or less have relatively excellent impact resistance and folding reliability compared to Comparative Examples 1 to 4 in which a value obtained by dividing the first length L1 by the second length L2 does not satisfy 0.05 or more and 0.5 or less.

As an example, comparing Example 1 and Comparative Example 1, in Example 1, a minimum height at which the plate breaks in the ball drop test is 5 cm, and in Comparative Example 1, a minimum height is 3 cm. That is, an impact resistance in Example 1 is more superior than in Comparative Example 1. In addition, in the wrinkle measurement experiment, 60 μm wrinkles were formed in Example 1 and 100 μm wrinkles were formed in Comparative Example 1, confirming that Example 1 has relatively excellent impact resistance and folding reliability.

In addition, comparing Example 1 and Comparative Example 4, in Example 1, a shape of the plate was good even after 200,000 times of folding and unfolding in an experiment measuring deformation. In Comparative Example 4, a shape was deformed and was not good, and, thus, it can be seen that a folding reliability was relatively good in Example 1.

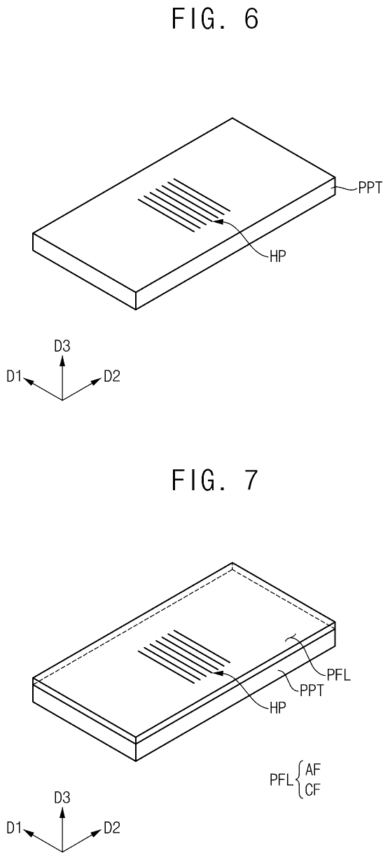

FIGS. 6 to 11 are views showing a method of manufacturing a display device according to an embodiment of the present disclosure.

Referring to FIG. 6, openings HP that continuously extend in the first direction D1 may be formed in a preliminary plate PPT. For example, the openings HP may be formed using a laser. Each of the openings HP may be formed to be spaced apart from each other in the second direction D2.

The openings HP may be formed such that a value obtained by dividing a width of each of the openings HP in the second direction D2 by a separation distance of the openings HP adjacent to each other in the second direction D2 among the openings HP may be 0.05 (0.05 or about 0.05) to 0.5 (0.5 or about 0.5). In an embodiment, a width of the openings HP in the second direction D2 may be 20 μm (20 μm or about 20 μm) to 1000 μm (1000 μm or about 1000 μm). In an embodiment, a separation distance between the openings HP adjacent to each other may be 200 μm (200 μm or about 200 μm) to 5000 μm (5000 μm or about 5000 μm).

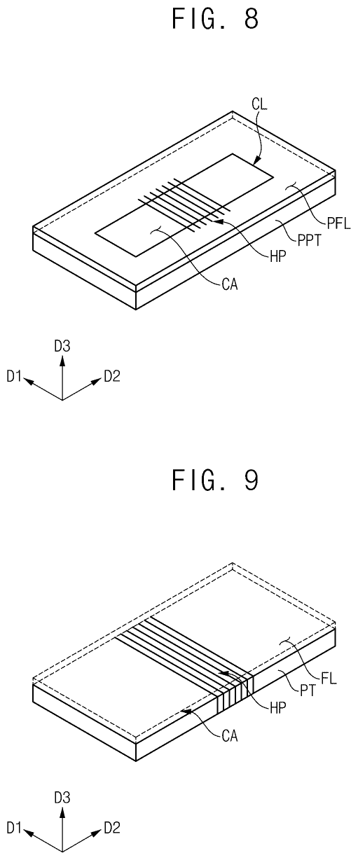

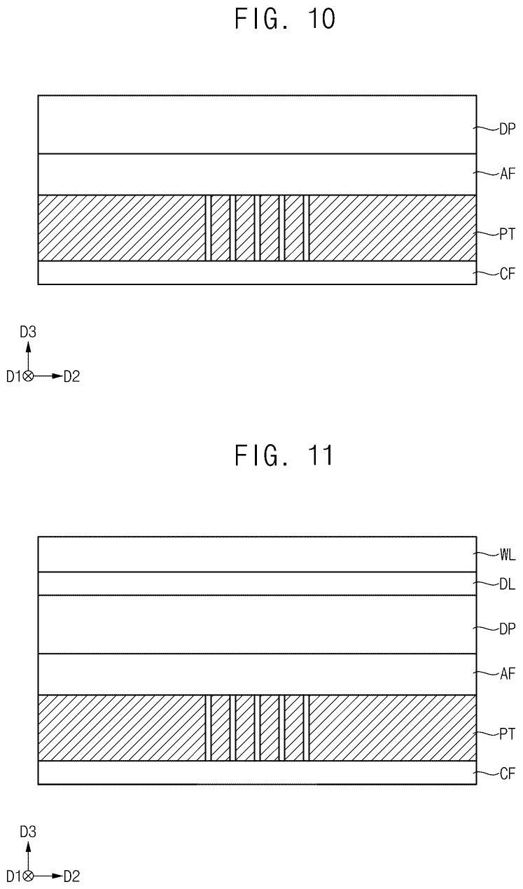

Referring further to FIG. 7, a preliminary film PFL may be attached to a surface of the preliminary plate PPT. That is, the preliminary film PFL may be attached to the preliminary plate PPT in the third direction D3 or in a direction opposite to the third direction D3. For example, the preliminary film PFL may be any of the adhesive film AF or the cover film CF described with respect to FIG. 3. As the preliminary film PFL is attached to a surface of the preliminary plate PPT, the plate PT may be integrally formed without being cut by the openings HP after the cutting in FIGS. 8 and 9.

Referring further to FIGS. 8 and 9, the preliminary plate PPT and the preliminary film PFL may be cut along a closed loop-shaped cutting line CL. Accordingly, the plate PT to which the film FL is attached may be formed. The plate PT may be cut concurrently (e.g., simultaneously) with the film FL. For example, the plate PT may be cut concurrently (e.g., simultaneously) with the film FL using a laser along the cutting line CL. A length of a cutting area CA formed by the cutting line CL in the first direction D1 may be smaller than a length of each of the openings HP in the first direction D1. As a result, a length of each of the openings HP in FIG. 9 in the first direction D1 may be equal to a length of the plate PT in the first direction D1.

In an embodiment, a distance between the adjacent openings HP divided by a length of the plate PT in the first direction D1 may be 0.003 (0.003 or about 0.003) to 0.04 (0.04 or about 0.04). In an embodiment, a separation distance between the adjacent openings HP divided by a length of the plate PT in the first direction D1 may be 0.003 (0.003 or about 0.003) to 0.02 (0.02 or about 0.02).

After the plate PT and the film FL are cut concurrently (e.g., simultaneously), a length of each of the openings HP in the first direction D1 and a length of the plate PT in the first direction D1 may be the same (the same or substantially the same). For example, the plate PT may have a rectangular shape in a plan view.

Referring to FIGS. 10 and 11, the display panel DP, the damping layer DL, and the window layer WL may be further attached sequentially. As a result, the display device DD shown in FIG. 3 may be manufactured.

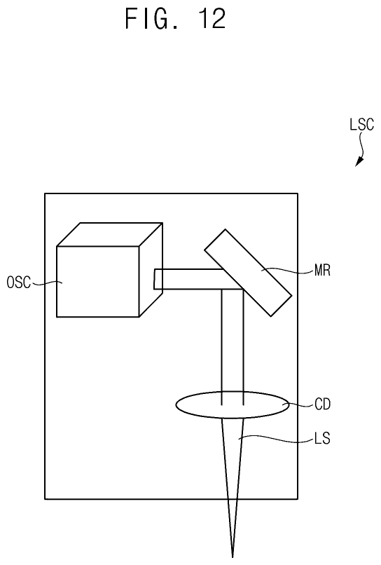

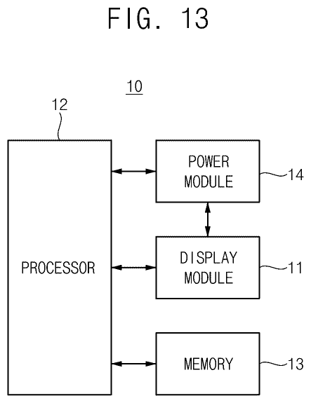

FIG. 12 is schematic view showing a laser cutter used in FIG. 6 and FIG. 8, according to an embodiment.

Referring to FIG. 12, a laser cutter LSC may include an oscillator OSC, a mirror MR, and a lens CD. The laser cutter LSC may be used to form the openings (e.g., the openings HP of FIG. 8) or to cut along the cutting line (e.g., the cutting line CL of FIG. 8).

In an embodiment, a laser LS oscillated from the oscillator OSC may be a CO₂ laser. In an embodiment, the laser LS may include any of a YAG laser, a solid-state laser including a sapphire laser, a He—Ne laser, an Ar+ laser, and a gas laser including an excimer laser. However, embodiments of the present disclosure are not limited thereto.

The oscillator OSC may oscillate the laser LS. In an embodiment, an output of the oscillator OSC may be about 5 watts or more and about 100 watts or less. In an embodiment, an output of the oscillator OSC may be about 10 watts or more and about 50 watts or less. However, embodiments of the present disclosure are not limited thereto.

As a result, the laser LS oscillated from the oscillator OSC may be reflected by the mirror MR, focused on the lens CD, and irradiated to the plate (e.g., the plate PT in FIG. 8).

The present disclosure may be applied to the display device and an electronic device including the same. For example, the present disclosure may be applied to high-resolution smartphones, mobile phones, smart pads, smart watches, tablet PCs, vehicle navigation systems, televisions, computer monitors, laptops, etc.

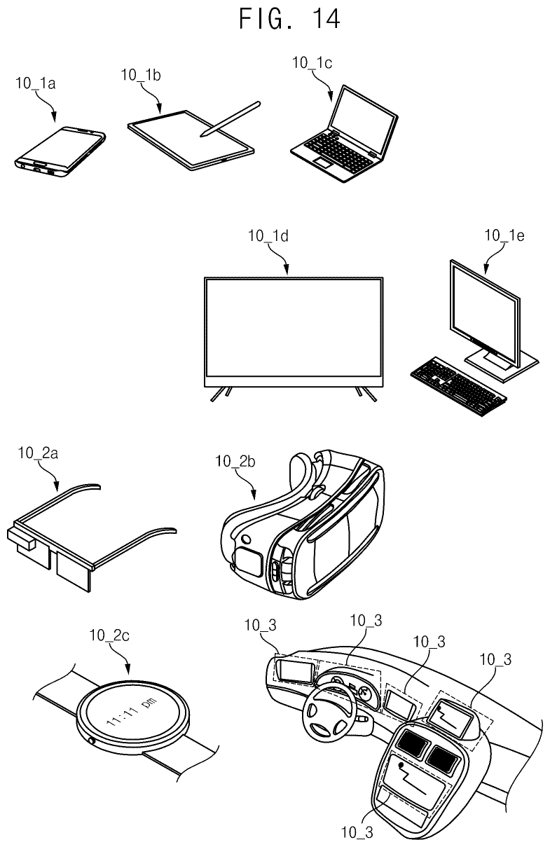

FIG. 13 is block-diagram for showing an electronic device according to an embodiment of the disclosure.

Referring to FIG. 1 and FIG. 13, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

FIG. 14 is schematic views for showing the electronic device according to various embodiments of FIG. 13.

Referring to FIGS. 13 and 14, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

While the present disclosure has been particularly shown and described with reference to some example embodiments thereof, it will be understood by those of ordinary skill in the art that various changes in form and details may be made therein without departing from the spirit or scope of the disclosure as defined by the claims.

What is claimed is:

1. A display device comprising:
a display panel comprising a folding area; and
a plate located below the display panel, and defining a plurality of openings extending continuously in a first direction and spaced apart from each other in a second direction intersecting the first direction, and
a value obtained by dividing a width of each of the openings in the second direction by a separation distance of adjacent openings among the openings in the second direction is 0.05 to 0.5.

2. The display device of claim 1, wherein each of the openings entirely penetrates the plate in the first direction.

3. The display device of claim 1, wherein a value obtained by dividing the separation distance by a length of the plate in the first direction is 0.003 to 0.04.

4. The display device of claim 1, wherein a length of each of the openings in the first direction is equal to a length of the plate in the first direction.

5. The display device of claim 1, wherein the openings are defined in the folding area below the display panel.

6. The display device of claim 1, further comprising:
an adhesive film between the display panel and the plate; and
a cover film below the plate.

7. The display device of claim 6, wherein the adhesive film and the openings overlap in the folding area in a plan view.

8. The display device of claim 6, wherein a planar area of the plate is equal to at least one of a planar area of the adhesive film or the cover film.

9. The display device of claim 1, wherein the width of each of the openings is 20 μm to 1000 μm, and the separation distance is 200 μm to 5000 μm.

10. The display device of claim 1, wherein the plate comprises at least one of a plastic, a metal, or glass.

11. The display device of claim 10, wherein the plastic comprises at least one of carbon fiber reinforced plastic or glass fiber reinforced plastic.

12. The display device of claim 10, wherein the metal comprises at least one of stainless steel, aluminum, magnesium, or copper.

13. A method of manufacturing a display device, the method comprising:
forming a plurality of openings in a preliminary plate using a laser, the openings continuously extending in a first direction and spaced apart from each other in a second direction intersecting the first direction;
attaching a preliminary film to a surface of the preliminary plate; and
forming a plate to which a film is attached by cutting the preliminary plate and the preliminary film concurrently along a closed loop-shaped cutting line.

14. The method of claim 13, wherein the openings are formed such that a width of each of the openings in the second direction divided by a separation distance of adjacent openings among the openings in the second direction is 0.05 to 0.5.

15. The method of claim 14, wherein the width of each of the openings is 20 μm to 1000 μm, and the separation distance between the adjacent openings in the second direction is 200 μm to 5000 μm.

16. The method of claim 14, wherein the preliminary plate and the preliminary film are cut such that a value obtained by dividing the separation distance between the adjacent openings by a length of the plate in the first direction is 0.003 to 0.04.

17. The method of claim 13, wherein a cutting area defined by the cutting line overlaps the openings in a plan view.

18. The method of claim 13, wherein, after forming the plate to which the film is attached, a length of each of the openings in the first direction is equal to a length of the plate in the first direction.

19. The method of claim 13, wherein a planar area of the plate and a planar area of the film are the same.

20. The method of claim 13, wherein the preliminary plate and the preliminary film are cut using a laser.

21. An electronic device comprising:
a display device; and
a processor configured to drive the display device, and
wherein the display device includes:
a display panel comprising a folding area; and
a plate located below the display panel, and defining a plurality of openings extending continuously in a first direction and spaced apart from each other in a second direction intersecting the first direction, and
a value obtained by dividing a width of each of the openings in the second direction by a separation distance of adjacent openings among the openings in the second direction is 0.05 to 0.5.
